(19) United States
(12) Patent Application Publication
(10) Pub. No.: US 2009/0224988 A1
(43) Pub. Date: Sep. 10, 2009

(54) SATELLITE TRACKING MODE-SELECTABLE SATELLITE ANTENNA SYSTEM

(75) Inventor: Chan Goo PARK, Daejeon (KR)

Correspondence Address: KNOBBE MARTENS OLSON & BEAR LLP, 2040 MAIN STREET, FOURTEENTH FLOOR, IRVINE, CA, 92614, US

(73) Assignee: WIWORLD CO., LTD., Daejeon (KR)

(21) Appl. No.: 12/398,698

(22) Filed: Mar. 5, 2009

Related U.S. Application Data
(63) Continuation of application No. PCT/KR2007/004296, filed on Sep. 6, 2007.

(30) Foreign Application Priority Data
Sep. 6, 2006 (KR) 10-2006-0085774

(51) Int. Cl. H01Q 3/00; G01R 29/08

(52) U.S. Cl. 343/703; 343/766

(57) ABSTRACT

A satellite tracking mode-selectable satellite antenna system is disclosed. In one embodiment, the satellite antenna system includes an antenna unit installed in a mobile body for receiving a satellite signal, a motor unit for rotating an oriented direction of the antenna unit, an outdoor unit (ODU) for driving the motor unit to orient the antenna unit toward a satellite, and an indoor unit (IDU) for controlling the ODU to orient the antenna unit toward the satellite. The satellite antenna system further includes a gyro sensor unit detachably installed in the mobile body for sensing motion of the mobile body. One embodiment of the invention is capable of selecting an in-motion mode of tracking and acquiring the initial position of a satellite and then continuously tracking the position of the satellite, or a positioner mode of tracking and acquiring the initial position of the satellite and then fixing the oriented direction of an antenna.

### RELATED APPLICATIONS

This application is a continuation application, and claims the benefit under 35 U.S.C. §§ 120 and 365 of PCT Application No. PCT/KR2007/004296, filed on Sep. 6, 2007, which is hereby incorporated by reference. PCT/KR2007/004296 claimed the benefit of Korean Patent Application No. 10-2006-0085774 filed Sep. 6, 2006, which is hereby incorporated by reference.

### BACKGROUND OF THE INVENTION

1. Field of the Invention

The present invention relates to satellite antenna systems.

2. Description of the Related Technology

In general, satellite antennas include a fixed parabolic antenna installed in a home, a positioner antenna installed in a mobile body for receiving a satellite signal under the condition that the mobile body is stopped, and an in-motion antenna installed in a mobile body for tracking the position of a satellite to receive a satellite signal, while the mobile body is in motion.

### SUMMARY OF CERTAIN INVENTIVE ASPECTS

One aspect of the present invention is a satellite antenna system which has an integrated version of the structures of a positioner antenna system and an in-motion antenna system and employs two modes for the integrated version.

Another aspect of the present invention is a satellite antenna system wherein satellite tracking function elements can be added when the satellite tracking function is required while the antenna system is used for a positioner antenna function, so that the positioner antenna function and an in-motion antenna function can be selectively used as needed.

Another aspect of the present invention is a satellite antenna system wherein a control program for acquiring and tracking a satellite can be readily modified or upgraded.

Another aspect of the present invention is a satellite antenna system which is capable of, when the system is in an in-motion mode during long parking of a mobile body, switching the in-motion mode to a positioner mode to maintain the advantage of a positioner antenna system of small current consumption.

Another aspect the present invention is a satellite tracking mode-selectable satellite antenna system comprising an antenna unit installed in a mobile body for receiving a satellite signal, a motor unit for rotating an oriented direction of the antenna unit, an OutDoor Unit (ODU) for driving the motor unit to orient the antenna unit toward a satellite, and an InDoor Unit (IDU) for controlling the ODU to orient the antenna unit toward the satellite, the system further comprising a gyro sensor unit detachably installed in the mobile body for sensing motion of the mobile body, wherein the IDU selectively drives an in-motion mode of tracking and acquiring an initial position of the satellite, continuously tracking a position of the satellite based on information regarding the motion of the mobile body sensed by the gyro sensor unit and controlling the rotation of the antenna unit based on the continuously tracked position, and a positioner mode of tracking and acquiring the initial position of the satellite and then fixing the oriented direction of the antenna unit.

Another aspect of the invention is a satellite tracking mode-selectable satellite antenna system comprising an antenna unit installed in a mobile body configured to receive a satellite signal, a motor unit configured to rotate an oriented direction of the antenna unit, an outdoor unit (ODU) configured to drive the motor unit to orient the antenna unit toward a satellite, and an indoor unit (IDU) configured to control the ODU to orient the antenna unit toward the satellite, the system further comprising: a gyro sensor unit detachably installed in the mobile body and configured to sense motion of the mobile body, wherein the IDU is configured to selectively drive one of (1) an in-motion mode of tracking and acquiring an initial position of the satellite, continuously tracking a position of the satellite based on information regarding the motion of the mobile body sensed by the gyro sensor unit and controlling the rotation of the antenna unit based on the continuously tracked position, and (2) a positioner mode of tracking and acquiring the initial position of the satellite and then fixing the oriented direction of the antenna unit.

In the above system, the IDU comprises: a switch unit configured to select any one of the in-motion mode and the positioner mode; a tuner configured to receive the satellite signal received by the antenna unit via the ODU and detect a strength of the received satellite signal; and a central controller configured to i) register a main control program therein, the main control program, in the mode selected by the switch unit, ii) analyze the satellite signal strength detected by the tuner and an output value from the gyro sensor unit, iii) track the position of the satellite based on the analysis results and iv) control an operation of the ODU based on the tracked position to perform the in-motion mode or positioner mode.

In the above system, the ODU comprises: a mode discriminator configured to discriminate a satellite tracking mode as any one of the in-motion mode and the positioner mode in response to a control signal transmitted from the IDU; a central controller configured to register a sub control program therein, the sub control program is configured to generate drive signals to an elevation mode and an azimuth motor of the motor unit in response to a control signal for compensation for the motion of the mobile body transmitted from the main control program registered in the central controller of the IDU; and a motor driver configured to rotate the antenna unit to a position oriented toward the satellite in response to the drive signals from the central controller of the ODU.

In the above system, the main control program registered in the central controller of the IDU is updatable or modifiable, and wherein the sub control program registered in the central controller of the ODU includes a fixed sub function algorithm driven by a remote control of the main control program.

In the above system, the sub control program registered in the central controller of the ODU comprises: a gyro sensor calibration module configured to set an output reference value of a gyro sensor of the gyro sensor unit; a motor position control module configured to control a motor position of the motor unit rotating the oriented direction of the antenna unit; and a gyro sensor-associated motor control module configured to control the rotation of the motor unit in association with the gyro sensor of the gyro sensor unit; and wherein the main control program registered in the central controller of the IDU comprises: a satellite tracking module configured to acquire and track a position of a satellite; a satellite selection module configured to select a satellite from which a signal is to be received; and a satellite identification check module configured to determine whether a satellite from which a signal is received is the satellite selected by the satellite selection module. In the above system, the IDU and the ODU are configured to be powered off after the initial position of the satellite is acquired in the positioner mode.

Still another aspect of the invention is a satellite tracking mode-selectable satellite antenna system, comprising: an antenna installed in a mobile body configured to receive a satellite signal; a motor configured to rotate an oriented direction of the antenna; a first controller configured to drive the motor to orient the antenna toward a satellite; a second controller configured to control the first controller to orient the antenna toward the satellite; and a gyro sensor detachably installed in the mobile body and configured to sense motion of the mobile body, wherein the second controller is further configured to selectively drive one of an in-motion mode and a positioner mode, wherein the in-motion mode is configured to i) track and acquire an initial position of the satellite, ii) continuously track a position of the satellite based on information regarding the motion of the mobile body sensed by the gyro sensor and iii) control the rotation of the antenna based on the continuously tracked position, and wherein the positioner mode is configured to i) track and acquire the initial position of the satellite and ii) fix the oriented direction of the antenna.

### BRIEF DESCRIPTION OF THE DRAWINGS

FIG. 1 is a block diagram schematically showing the configuration of a positioner antenna system.

FIG. 2 is a block diagram schematically showing the configuration of an in-motion antenna system.

FIG. 3 is an installation diagram of a satellite antenna system according to one embodiment of the present invention.

FIGS. 4 and 5 are perspective views of the satellite antenna system which is installed outside of a mobile body in accordance with one embodiment of the present invention.

FIG. 6 is a block diagram showing the configuration of the satellite antenna system according to one embodiment of the present invention.

FIG. 7 is a block diagram illustrating examples of control programs according to one embodiment of the present invention.

FIGS. 8 and 9 are flowcharts illustrating a process of the satellite antenna system acquiring and tracking a satellite in accordance with one embodiment of the present invention.

### DETAILED DESCRIPTION OF CERTAIN INVENTIVE EMBODIMENTS

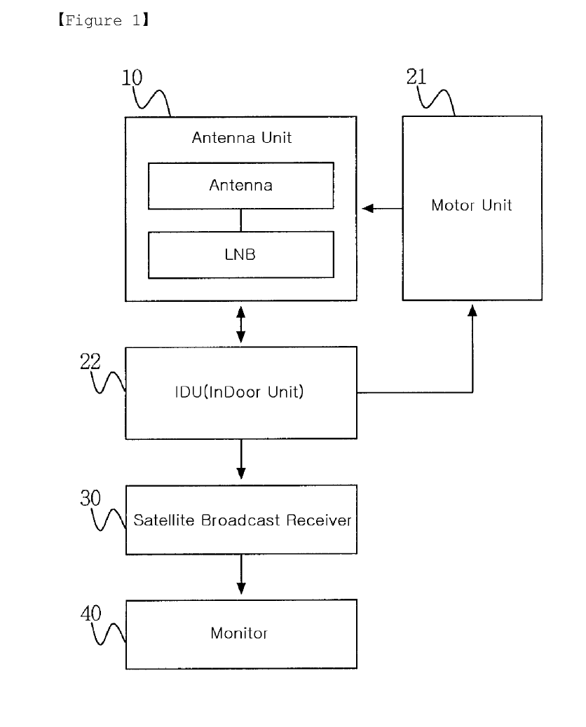

FIG. 1 is a block diagram schematically showing the configuration of a positioner antenna system.

As shown in FIG. 1, the positioner antenna system comprises an antenna unit 10 including an antenna for receiving a satellite signal, and a Low Noise Block (LNB) down converter for converting the received satellite signal into an intermediate frequency (IF) signal, a motor unit 21 for rotating the antenna unit 10 in a direction oriented toward a satellite, an InDoor Unit (IDU) 22 for acquiring the initial position of the satellite and controlling the motor unit 21 based on the acquired initial position, and a satellite broadcast receiver 30 for displaying a satellite signal transmitted from the IDU 22 through a monitor 40.

In the above positioner antenna system, if the IDU 22 acquires the initial position of the satellite, then it controls the motor unit 21 based on the acquired initial position to rotate and fix the antenna unit 10 in the satellite-oriented direction. Thereafter, the IDU 22 is powered off, and the satellite broadcast receiver 30 is thus connected directly with the LNB down converter of the antenna unit 10 to supply power to the LNB down converter and receive a satellite signal from the LNB down converter.

This positioner antenna system is advantageous in that it is small in power consumption, relatively simple in construction and thus low in manufacturing cost, because the IDU is powered off after tracking and acquiring the initial position of the satellite. However, this positioner antenna system has a disadvantage in that it cannot receive a satellite signal when an associated mobile body is in motion, because it has no function of continuously tracking the satellite after acquiring the initial position of the satellite.

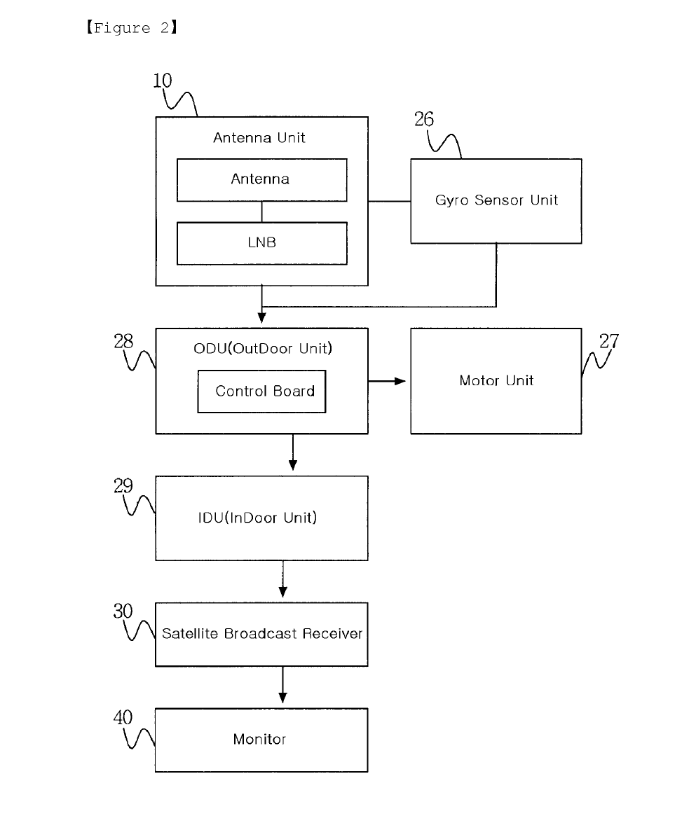

FIG. 2 is a block diagram schematically showing the configuration of an in-motion antenna system.

As shown in FIG. 2, the in-motion antenna system comprises an antenna unit 10 including an antenna and an LNB down converter, a gyro sensor unit 26 for sensing the motion of a mobile body equipped with the antenna unit 10, a motor unit 27 for rotating the antenna unit 10 in an azimuth direction and an elevation direction, an IDU 29 for selecting and confirming a satellite from which a signal is to be received, an OutDoor Unit (ODU) 28 for tracking the position of the selected satellite and controlling the motor unit 27 based on the tracking result to orient the antenna unit 10 toward the selected satellite, and a satellite broadcast receiver 30 for displaying a satellite signal transmitted from the IDU 22 through a monitor 40.

The above in-motion antenna system is an active antenna system which is capable of receiving a satellite signal even when the mobile body is in motion, by continuously tracking the position of the satellite based on the motion of the mobile body sensed by the gyro sensor unit 26 after acquiring the initial position of the satellite.

However, this in-motion antenna system has a disadvantage in that it is higher in manufacturing cost than the positioner antenna system because it is complex in construction. Further, a large amount of power consumption is required because the IDU 29 and ODU 28 are continuously driven irrespective of the moved or stopped state of the mobile body to track the satellite. In addition, noise frequently occurs due to the continuous motion of the antenna unit 10. Furthermore, the ODU 28 is installed outside of the mobile body and a satellite tracking control program is provided in the ODU 28. For this reason, a programmer has to modify or upgrade the satellite tracking control program after separating the ODU 28 from the mobile body, resulting in difficulty in modifying or upgrading the program.

On the other hand, these positioner antenna and in-motion antenna systems are separately manufactured and operated. For this reason, in order to add a satellite tracking function as needed in the middle of purchasing and using the positioner antenna system, the user has to separately purchase the costly in-motion antenna system with a large economic burden.

Reference will now be made in detail to embodiments of the present invention, examples of which are illustrated in the accompanying drawings. Wherever possible, the same reference numbers will be used throughout the drawings to refer to the same or like parts, and a duplicate description thereof will be omitted.

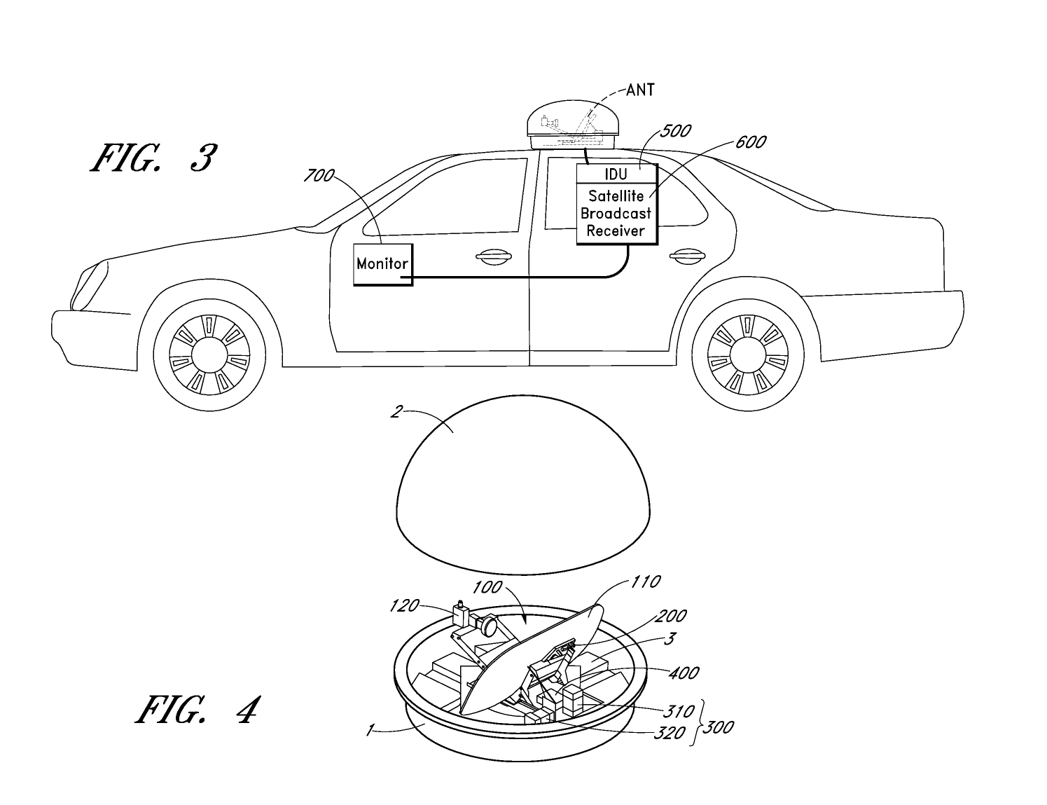

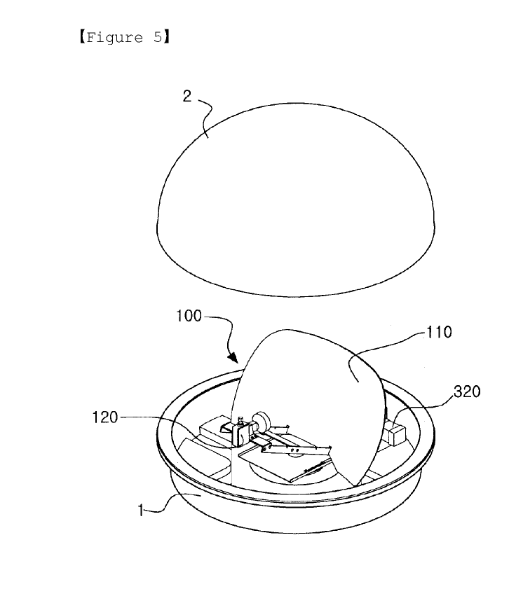

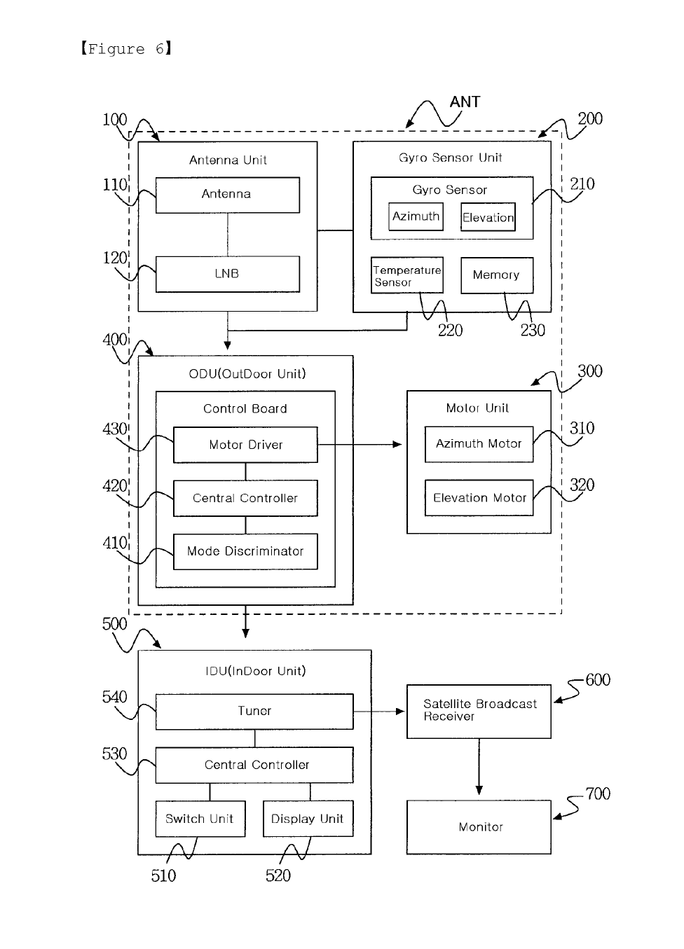

FIG. 3 is an installation diagram of a satellite antenna system according to an embodiment of the present invention, FIGS. 4 and 5 are perspective views of the satellite antenna system which is installed outside of a mobile body, and FIG. 6 is a block diagram showing the configuration of the satellite antenna system.

As shown in FIGS. 3 to 6, the satellite antenna system according to one embodiment of the present invention comprises an antenna unit 100 for receiving a satellite signal, a gyro sensor unit 200 for sensing the motion of a mobile body equipped with the antenna unit 100, a motor unit 300 for rotating the antenna unit 100, and an ODU 400 for controlling the motor unit 300 based on the position of a satellite. The antenna unit 100, gyro sensor unit 200, motor unit 300 and ODU 400 are installed outside of the mobile body in such a manner that they are rotatably installed on a base plate 3 mounted on the inside of a lower cover 1, formed integrally with one another and protected by an upper cover 2, as indicated by ANT. In one embodiment, the satellite antenna system further comprises an IDU 500 for controlling the operation of the ODU 400, and analyzing a satellite signal transmitted from the ODU 400 and acquiring and tracking the position of the satellite based on the analysis result, and a satellite broadcast receiver 600 for displaying a satellite signal transmitted from the IDU 500 through a monitor 700. The IDU 500, satellite broadcast receiver 600 and monitor 700 are installed inside of the mobile body.

The antenna unit 100 includes an antenna 110 for receiving a satellite signal from the satellite, and an LNB down converter 120 for converting the satellite signal received through the antenna 110 into an IF satellite signal and transmitting the converted IF satellite signal to the ODU 400.

The gyro sensor unit 200 includes a gyro sensor 210 for sensing azimuth and elevation variations of the mobile body equipped with the antenna unit 100, a sensor 220 for measuring an ambient temperature, and a memory 230 for storing output reference values of the gyro sensor 210 by ambient temperatures. The motor unit 300 includes an azimuth motor 310 for rotating the antenna unit 100 in an azimuth direction under control of the ODU 400, and an elevation motor 320 for rotating the antenna unit 100 in an elevation direction under the control of the ODU 400.

The ODU 400 has a control board including a mode discriminator 410 for comparing the level of a voltage transmitted from the IDU 500 with a reference value, and discriminating a satellite tracking mode set by the IDU 500 as an in-motion mode when the voltage level is higher than or equal to the reference value and as a positioner mode when the voltage level is lower than the reference value, a central controller 420 for transmitting the satellite signal transmitted from the antenna unit 100 to the IDU 500, analyzing an output value from the gyro sensor unit 200 and, based on the analysis result, generating a drive signal to drive the motor unit 300 to track the position of the satellite, and a motor driver 430 for driving the motor unit 300 in response to the drive signal from the central controller 420.

In the central controller 420 of the ODU 400 is registered a sub satellite tracking control program which controls the motor unit 300 under control of a main satellite tracking control program registered in a central controller of the IDU 500.

When the satellite tracking mode is the positioner mode, the ODU 400 acquires the initial position of the satellite, rotates the antenna unit 100 toward the acquired initial satellite position, and is then powered off so as to be stopped in operation, thus preventing unnecessary power consumption.

The IDU 500 includes a tuner 540 for receiving the satellite signal from the ODU 400, a central controller 530 for analyzing the satellite signal received through the tuner 540 and acquiring and tracking the position of the satellite based on the analysis result, a switch unit 510 for setting the operation of the satellite antenna system, and a display unit 520 for displaying the set state and operating state of the satellite antenna system.

The tuner 540 also transmits the received IF satellite signal to the satellite broadcast receiver 600 to display it through the monitor 700.

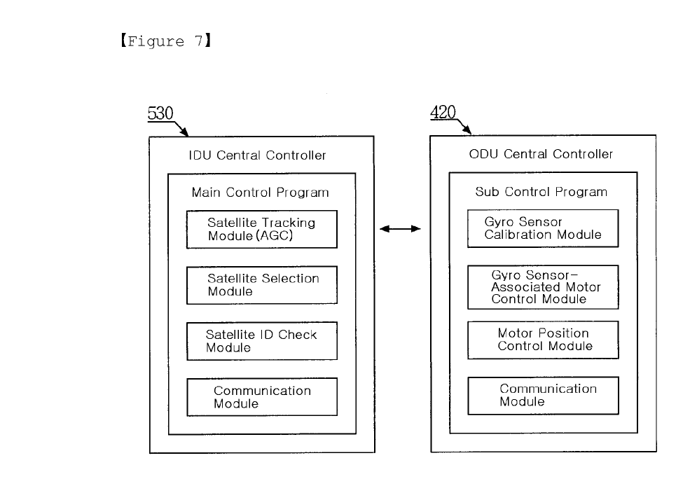

FIG. 7 illustrates examples of the control programs registered in the central controllers of the IDU and ODU.

As shown in FIG. 7, the main control program registered in the central controller 530 of the IDU 500 includes a satellite tracking module for analyzing the automatic gain control (AGC) level of a satellite signal, tracking and acquiring the initial position of a satellite based on the analysis result, analyzing an output value from the gyro sensor 210 and the acquired initial satellite position and continuously tracking the position of the satellite based on the analysis results, a satellite selection module for selecting a satellite from which a signal is to be received, a satellite identification (ID) check module for checking an ID of a satellite from which a signal is received, to determine whether the satellite is the selected satellite, and a communication module for communication with the sub control program registered in the central controller 420 of the ODU 400. This main control program can be modified or updated for improvement in function.

The sub control program registered in the central controller 420 of the ODU 400 is a sub function algorithm which is remotely controlled by the main control program, and includes a gyro sensor calibration module for performing a calibration to set an output reference value of the gyro sensor 210, a gyro sensor-associated motor control module for controlling the rotation of the motor unit 300 in association with an output value from the gyro sensor 210 of the gyro sensor unit 200 and the satellite tracking module of the IDU 500, a motor position control module for controlling a motor position of the motor unit 300, and a communication module for communication with the main control program registered in the central controller 530 of the IDU 500. This sub control program does not need to be separately modified or updated, because it is remotely controlled by the main control program, and can be changed or improved in function as the main control program is modified or updated.

In one embodiment, the main control program functions to select a satellite, acquire the initial position of the selected satellite and continuously track the position of the initial position-acquired satellite, and the sub control program functions to control the motor unit 300. The sub control program whose modification or update is not required is registered in the central controller 420 of the ODU 400, and the main control program whose modification or update is required is registered in the central controller 530 of the IDU 500. The reason is that the provision of the main control program in the IDU 500 installed inside of the mobile body for execution of both the positioner antenna function and in-motion antenna function is advantageous in terms of program modification or update over a positioner antenna system in which a main control program is provided in an IDU and an in-motion antenna system in which a main control program is provided in an ODU.

A description will hereinafter be given of the operation of the satellite antenna system with the above-stated configuration according to one embodiment.

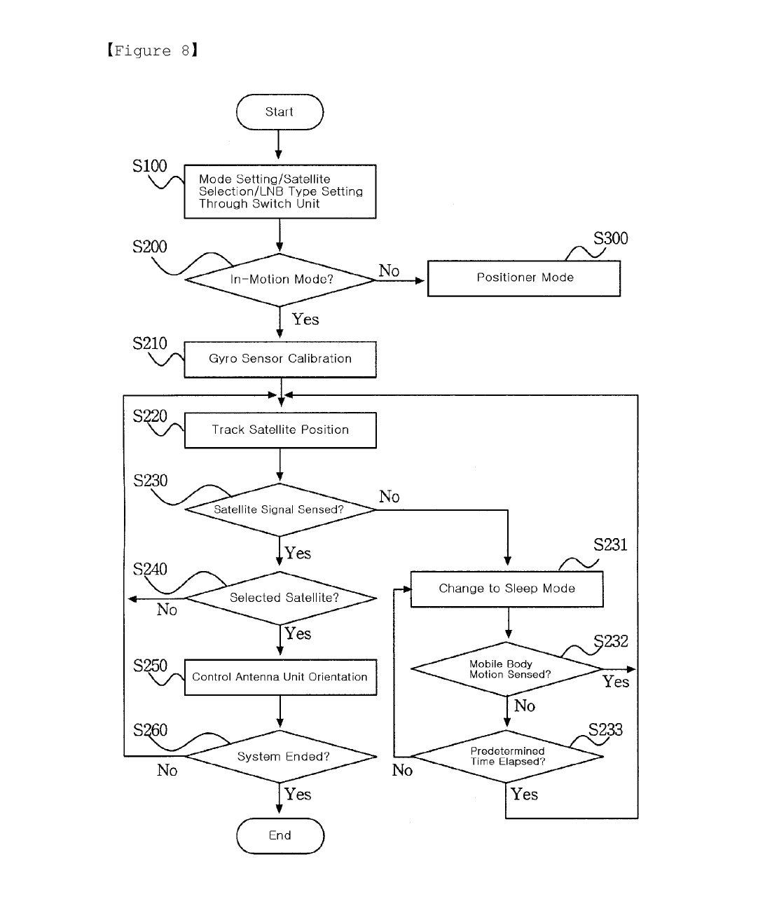

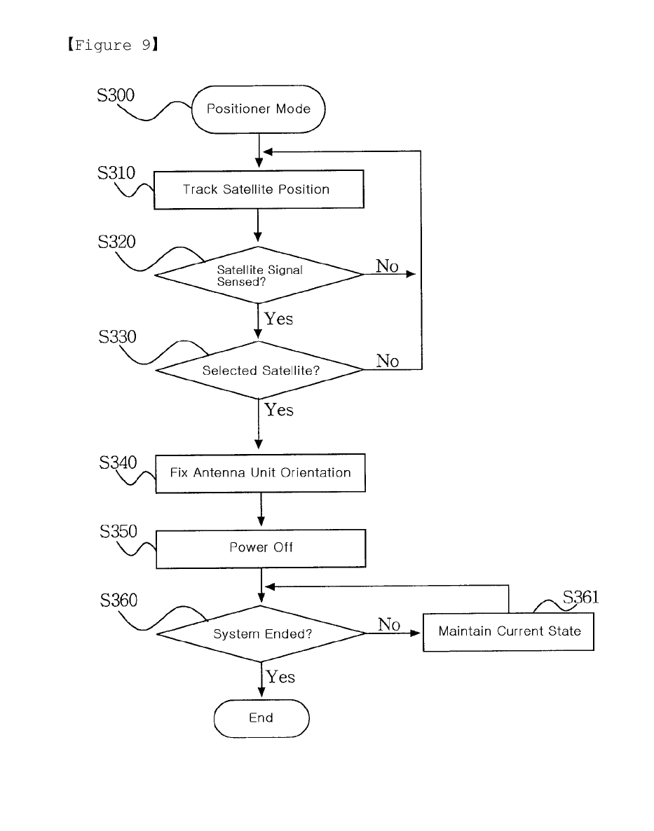

FIGS. 8 and 9 are flowcharts illustrating a process of the satellite antenna system acquiring and tracking a satellite in accordance with one embodiment.

Step 100: First, the user operates the switch unit 510 provided in the IDU 500 to set a satellite tracking mode, select a satellite from which a signal is to be received, set satellite broadcast reception environments including an LNB type, and turn a power switch on.

Steps S200, S210 and S220: When the satellite tracking mode set at the above step is the in-motion mode (S200), the central controller 530 of the IDU 500 first performs a calibration to set an output reference value of the gyro sensor unit 200, through the sub control program provided in the central controller 420 of the ODU 400, (S210) and then tracks the position of the selected satellite while rotating the antenna unit 100 upward, downward, left and right (S220).

Steps S230 and S240: For satellite tracking, first, the central controller 530 of the IDU 500 determines whether there is a satellite signal sensed through the antenna unit 100 (S230). If a satellite signal is sensed, the central controller 530 checks a satellite ID contained in the sensed satellite signal to determine whether the sensed satellite signal has been sent from the satellite selected at step S100 (S240). Upon determining that the sensed satellite signal has not been sent from the selected satellite, the central controller 530 discards the sensed satellite signal and returns to step S220 to receive a new satellite signal.

Steps S231, S232 and S233: If it is determined at step S230 that there is no satellite signal sensed, the central controller 530 of the IDU 500 changes the satellite tracking mode to a sleep mode (S231). Thereafter, if the motion of the mobile body is sensed through the gyro sensor unit 200 (S232) or if a predetermined time elapses (S233), the central controller 530 returns to step S220 to repeat the satellite signal tracking operation.

Step S250: On the other hand, if it is determined at step S240 that the sensed satellite signal has been sent from the selected satellite, the central controller 530 of the IDU 500 analyzes the strength of a satellite signal transmitted from the ODU 400 and tracks and acquires the initial position of the satellite based on the analysis result. That is, the central controller 530 of the IDU 500 rotates the antenna unit 100 upward, downward, left and right based on the AGC level of a satellite signal received through the tuner 540 and acquires and sets a position where the signal strength is larger than a predetermined reference value during the rotation of the antenna unit 100, as the initial position of the satellite.

If the initial position of the satellite is acquired in the above manner, the central controller 530 of the IDU 500 analyzes the strength of a satellite signal which is transmitted from the antenna unit 100 through the ODU 400 and azimuth and elevation variation values outputted from the gyro sensor unit 200, generates a control signal for compensation for the motion of the mobile body based on the analysis results and transmits the generated control signal to the ODU 400. The ODU 400 then drives the motor unit 300 in response to the transmitted control signal to orient the antenna unit 100 toward the satellite being tracked.

Step S260: This satellite tracking process is continuously repeated until the system is ended.

Steps S300 and S310: On the other hand, in the case where the satellite tracking mode set at step S100 is the positioner mode (S300), the central controller 530 of the IDU 500 performs an operation of tracking the initial position of a satellite without a separate calibration (S310).

Steps S320 and S330: In order to track and acquire the initial position of a satellite, first, the central controller 530 of the IDU 500 determines whether there is a satellite signal sensed through the antenna unit 100 (S320). If a satellite signal is sensed, the central controller 530 determines whether the sensed satellite signal has been sent from the satellite selected at step S100 (S330). If it is determined that the sensed satellite signal has not been sent from the selected satellite, the central controller 530 discards the sensed satellite signal and returns to step S310 to receive a new satellite signal.

Step S340: If it is determined at step S330 that the sensed satellite signal has been sent from the selected satellite, the central controller 530 of the IDU 500 analyzes the strength of a satellite signal transmitted from the ODU 400 and tracks and acquires the initial position of the satellite based on the analysis result. The central controller 530 then transmits a control signal to the central controller 420 of the ODU 400 to orient and fix the antenna unit 100 toward the initial position-acquired satellite.

Step S350: If the oriented direction of the antenna unit 100 is fixed at the acquired initial position, the IDU 500, ODU 400 and motor unit 300 are powered off such that the supply of power thereto is cut off. That is, in the positioner mode, if the initial position of the satellite is acquired, the antenna unit 100 is fixed at the acquired initial position and thus performs no separate operation. Therefore, power to each constituent element, not operated, is cut off to prevent unnecessary power consumption. At this time, the LNB down converter 120 of the antenna unit 100 is connected directly with the satellite broadcast receiver 600 through the mode discriminator 410 of the ODU 400 and the tuner 540 of the IDU 500 to receive a drive voltage from the satellite broadcast receiver 600. The LNB down converter 120 also transmits a satellite signal received through the antenna unit 100 to the satellite broadcast receiver 600.

Step S360: If the system is not ended, the power-off state of the IDU 500, ODU 400 and motor unit 300 is continuously maintained under the condition that the oriented direction of the antenna unit 100 is fixed.

Through the above-described process, one satellite antenna system selectively performs the in-motion mode and the positioner mode to receive a satellite signal.

According to at least one embodiment of the present invention, one satellite antenna system can select an in-motion mode and a positioner mode to perform two different functions.

In addition, control programs for acquiring and tracking a satellite can be separately executed by an IDU and an ODU, so that they can be readily modified or upgraded.

Furthermore, a gyro sensor unit is additionally provided for an antenna system performing a positioner antenna function, so that an in-motion antenna function can also be performed by the antenna system. Therefore, it is possible to solve the cost and trouble of separately purchasing an in-motion antenna system.

Although embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A satellite tracking mode-selectable satellite antenna system comprising an antenna unit installed in a mobile body configured to receive a satellite signal, a motor unit configured to rotate an oriented direction of the antenna unit, an outdoor unit (ODU) configured to drive the motor unit to orient the antenna unit toward a satellite, and an indoor unit (IDU) configured to control the ODU to orient the antenna unit toward the satellite, the system further comprising:
a gyro sensor unit detachably installed in the mobile body and configured to sense motion of the mobile body,
wherein the IDU is configured to selectively drive one of (1) an in-motion mode of tracking and acquiring an initial position of the satellite, continuously tracking a position of the satellite based on information regarding the motion of the mobile body sensed by the gyro sensor unit and controlling the rotation of the antenna unit based on the continuously tracked position, and (2) a positioner mode of tracking and acquiring the initial position of the satellite and then fixing the oriented direction of the antenna unit.

2. The satellite tracking mode-selectable satellite antenna system according to claim 1, wherein the IDU comprises:
a switch unit configured to select any one of the in-motion mode and the positioner mode;
a tuner configured to receive the satellite signal received by the antenna unit via the ODU and detect a strength of the received satellite signal; and
a central controller configured to i) register a main control program therein, the main control program, in the mode selected by the switch unit, ii) analyze the satellite signal strength detected by the tuner and an output value from the gyro sensor unit, iii) track the position of the satellite based on the analysis results and iv) control an operation of the ODU based on the tracked position to perform the in-motion mode or positioner mode.

3. The satellite tracking mode-selectable satellite antenna system according to claim 2, wherein the ODU comprises:
a mode discriminator configured to discriminate a satellite tracking mode as any one of the in-motion mode and the positioner mode in response to a control signal transmitted from the IDU;
a central controller configured to register a sub control program therein, the sub control program is configured to generate drive signals to an elevation mode and an azimuth motor of the motor unit in response to a control signal for compensation for the motion of the mobile body transmitted from the main control program registered in the central controller of the IDU; and
a motor driver configured to rotate the antenna unit to a position oriented toward the satellite in response to the drive signals from the central controller of the ODU.

4. The satellite tracking mode-selectable satellite antenna system according to claim 3, wherein the main control program registered in the central controller of the IDU is updatable or modifiable,
and wherein the sub control program registered in the central controller of the ODU includes a fixed sub function algorithm driven by a remote control of the main control program.

5. The satellite tracking mode-selectable satellite antenna system according to claim 4, wherein the sub control program registered in the central controller of the ODU comprises:
a gyro sensor calibration module configured to set an output reference value of a gyro sensor of the gyro sensor unit;
a motor position control module configured to control a motor position of the motor unit rotating the oriented direction of the antenna unit; and
a gyro sensor-associated motor control module configured to control the rotation of the motor unit in association with the gyro sensor of the gyro sensor unit; and
wherein the main control program registered in the central controller of the IDU comprises:
a satellite tracking module configured to acquire and track a position of a satellite;
a satellite selection module configured to select a satellite from which a signal is to be received; and
a satellite identification check module configured to determine whether a satellite from which a signal is received is the satellite selected by the satellite selection module.

6. The satellite tracking mode-selectable satellite antenna system according to claim 1, wherein the IDU and the ODU are configured to be powered off after the initial position of the satellite is acquired in the positioner mode.

7. A satellite tracking mode-selectable satellite antenna system, comprising:
an antenna installed in a mobile body configured to receive a satellite signal;
a motor configured to rotate an oriented direction of the antenna;
a first controller configured to drive the motor to orient the antenna toward a satellite;
a second controller configured to control the first controller to orient the antenna toward the satellite; and
a gyro sensor detachably installed in the mobile body and configured to sense motion of the mobile body,
wherein the second controller is further configured to selectively drive one of an in-motion mode and a positioner mode, wherein the in-motion mode is configured to i) track and acquire an initial position of the satellite, ii) continuously track a position of the satellite based on information regarding the motion of the mobile body sensed by the gyro sensor and iii) control the rotation of the antenna based on the continuously tracked position, and wherein the positioner mode is configured to i) track and acquire the initial position of the satellite and ii) fix the oriented direction of the antenna.
